(19) United States
(12) Patent Application Publication
(10) Pub. No.: US 2024/0355758 A1
(43) Pub. Date: Oct. 24, 2024

(54) METHODS AND APPARATUS TO REDUCE STRESS BETWEEN SOCKETS AND ASSOCIATED INTEGRATED CIRCUIT PACKAGES HAVING GLASS CORES

(71) Applicant: Intel Corporation, Santa Clara, CA (US)

(72) Inventors: Steven Adam Klein, Chandler, AZ (US); Jason Gamba, Gilbert, AZ (US); Matthew Thomas Guzy, Phoenix, AZ (US); Nicholas Steven Haehn, Scottsdale, AZ (US); Tarek Adly Ibrahim, Mesa, AZ (US); Brandon Christian Marin, Gilbert, AZ (US); Srinivas Venkata Ramanuja Pietambaram, Chandler, AZ (US); Jacob John Schichtel, Chandler, AZ (US)

(73) Assignee: Intel Corporation, Santa Clara, CA (US)

(21) Appl. No.: 18/756,926

(22) Filed: Jun. 27, 2024

(51) Int. Cl. H01L 23/544; H01L 23/15; H01L 23/40

(52) U.S. Cl. CPC H01L 23/544; H01L 23/15; H01L 23/4006; H01L 2023/4087; H01L 2223/54426

(57) ABSTRACT

Systems, apparatus, articles of manufacture, and methods to reduce stress between sockets and associated integrated circuit packages having glass cores are disclosed. An example integrated circuit package includes: a semiconductor die, and a substrate including a glass core. The substrate includes a first surface, a second surface opposite the first surface, and a third surface between the first surface and the second surfaces. The first surface supports the semiconductor die. The second surface includes first contacts to electrical couple with second contacts in a socket. At least a portion of the third surface separated and distinct from the glass core.

### BACKGROUND

The demand for greater computing power and faster computing times continues to grow. This has led to higher-density connectors on computer hardware components to transfer signals more quickly. Some integrated circuit (IC) chips (e.g., a land grid array (LGA) IC chip, a ball grid array (BGA) IC chip, a pin grid array (PGA) IC chip, etc.) are communicatively coupled to printed circuit boards (PCBs) via sockets constructed to receive and electrically couple to contacts on the IC chips.

### BRIEF DESCRIPTION OF THE DRAWINGS

FIG. 1 is a top view of an example integrated circuit (IC) package heat dissipation component stack.

FIG. 2 is a cross-sectional side view of the example IC package heat dissipation component stack of FIG. 1 taken along the line 2-2 of FIG. 1 prior to assembly.

FIG. 3 is a top view of the example IC package heat dissipation component stack of FIG. 1 with the heatsink omitted.

FIG. 4 is a cross-sectional side view of the example IC package heat dissipation component stack of FIGS. 1-3 after tightening one of the fasteners on the heatsink.

FIG. 5 is an enlarged cross-sectional view of the substrate of the IC package of FIG. 1 pressed against the second alignment feature as shown in FIG. 4.

FIG. 6 is a perspective view of the example socket of FIGS. 1-5 that shows an enlarged view of the example second alignment feature of FIGS. 1-5.

FIG. 7 is a cross-sectional view of an example substrate of another example IC package pressed against another example alignment feature of another example socket.

FIG. 8 is a perspective view of the example socket of FIG. 7 that shows an enlarged view of the example alignment feature of FIG. 7.

FIG. 9 is a cross-sectional view of another example substrate of another example IC package pressed against the example alignment feature of the example socket of FIGS. 7 and 8.

FIG. 10 is a perspective view of the example socket of FIG. 9 that shows an enlarged view of the example alignment feature of FIG. 9.

FIGS. 11A-15C illustrate different example stages in an example process to manufacture the example substrate of FIGS. 1-6.

FIGS. 16A-17C illustrate different example stages in an example process to manufacture the example substrate of FIGS. 7 and 8.

FIGS. 18A-18C illustrate an example glass panel assembly that may be manufactured to produce the example substrate of FIGS. 9 and 10.

FIG. 19A is a perspective view of a corner of the example substrate of FIGS. 1-6.

FIG. 19B shows the same view as FIG. 19A but with the dielectric material of the buildup regions rendered see-through to show the glass core embedded therein.

FIG. 20A is a perspective view of a corner of the example substrate of FIGS. 7 and 8.

FIG. 20B shows the same view as FIG. 20A but with the dielectric material of the buildup regions rendered see-through to show the glass core embedded therein.

FIG. 21A is a perspective view of a corner of the example substrate of FIGS. 9 and 10.

FIG. 21B shows the same view as FIG. 21A but with the dielectric material of the buildup regions rendered see-through to show the glass core embedded therein.

FIG. 22 is a perspective view of a corner of another example substrate with the dielectric material rendered see-through to show an example glass core embedded therein.

FIG. 23 is a perspective view of a corner of another example substrate with the dielectric material rendered see-through to show another example glass core embedded therein.

FIG. 24 is a perspective view of a corner of another example substrate with the dielectric material rendered see-through to show another example glass core embedded therein.

FIG. 25 is a flowchart representative of an example method that may be performed to fabricate any one of the example package substrates disclosed herein.

FIG. 26 is a top view of a wafer including dies that may be included in an IC package constructed in accordance with teachings disclosed herein.

FIG. 27 is a cross-sectional side view of an IC device that may be included in an IC package constructed in accordance with teachings disclosed herein.

FIG. 28 is a cross-sectional view of an example IC package constructed in accordance with teachings disclosed herein.

FIG. 29 is a cross-sectional side view of an IC device assembly that may include an IC package constructed in accordance with teachings disclosed herein.

FIG. 30 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

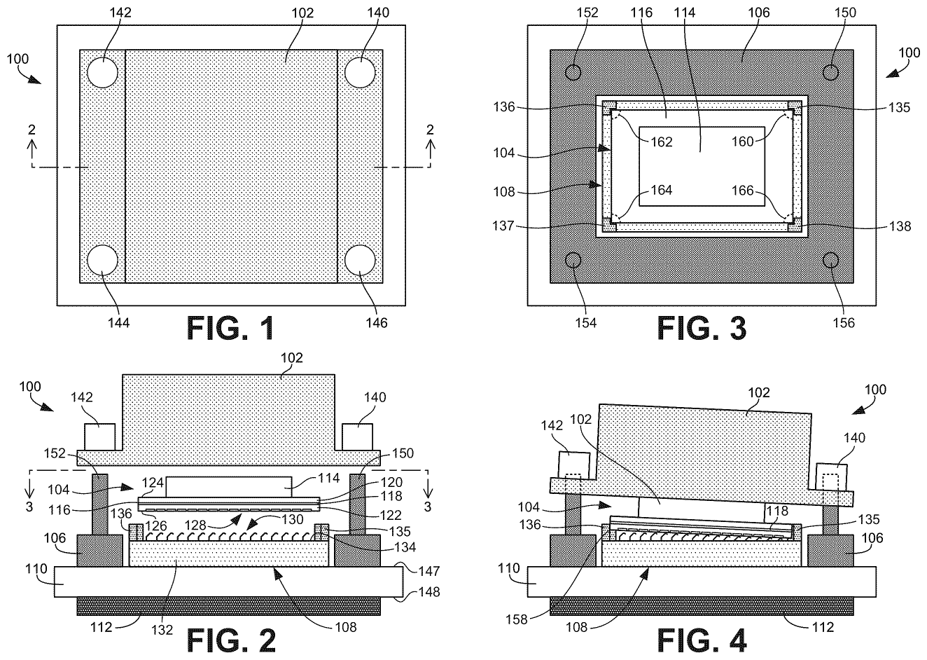

FIG. 1 is a schematic illustration of a top view of an example integrated circuit (IC) package heat dissipation component stack 100. FIG. 2 is a cross-sectional side view of the example IC package heat dissipation component stack 100 of FIG. 1 taken along the line 2-2 of FIG. 1 prior to assembly. That is, FIG. 2 is an exploded view with different components in the component stack 100 spaced apart. FIG. 3 is schematic illustration of a top view of the example component stack 100 of FIG. 1 with a heatsink 102 of the component stack 100 omitted to reveal the underlying components. That is, FIG. 3 corresponds to a view of the component stack 100 taken along the line 3-3 of FIG. 2. In the illustrated example of FIGS. 1-3, the component stack 100 includes the heatsink 102, an integrated circuit (IC) package 104, a bolster plate 106, a socket 108 coupled to a printed circuit board (PCB) (e.g., a motherboard) 110, and a back plate 112.

In this example, the IC package 104 includes integrated circuitry fabricated on a semiconductor (e.g., silicon) chip or die 114 that is mounted on an underlying substrate 116 (e.g., a package substrate, an interposer, etc.). In some examples, the IC package 104 includes more than one semiconductor die 114. The semiconductor die 114 can perform one or more processing function(s), memory function(s), and/or any other suitable function(s). The semiconductor die 114 can correspond to programmable circuitry that includes and/or implements any type of programmable processor(s), programmable microcontroller(s), central processing unit(s) (CPU(s)), graphics processing unit(s) (GPU(s)), digital signal processor(s) (DSP(s)), XPU(s), application specific integrated circuit(s) (ASIC(s)), programmable logic device(s) (PLD(s)), and/or field programmable logic device(s) (FPLD(s)) such as field programmable gate array(s) (FPGA(s)).

In the illustrated example, the substrate 116 of the IC package 104 includes a glass substrate, glass layer, or glass core 118 disposed between a first buildup region 120 (e.g., a first redistribution layer (RDL)) and a second buildup region 122 (e.g., a second RDL). In this example, the first buildup region 120 extends between the glass core 118 and a first surface 124 (e.g., a die-facing surface) of the substrate 116 that faces towards and supports the semiconductor die 114. The second buildup region 122 extends between the glass core 118 and a second surface 126 (e.g., a socket-facing surface) of the substrate 116 that faces towards the socket 108. The substrate 116 includes conductive interconnects defined within the buildup regions 120, 122 and through the glass core 118 to electrically couple the semiconductor die 114 on the first surface 124 of the substrate 116 with package contacts 128 (e.g., first contacts, first connectors, package connectors) on the second surface 126 of the substrate 116. In the illustrated example, the buildup regions 120, 122 are composed of layers of dielectric material that separates intervening layers of metal (e.g., copper) that have been patterned to define traces and/or other conductive features for the interconnects that extend through the substrate 116. In such examples, the different layers of metal are electrically coupled by metal vias extending through the layers of dielectric material. In this example, the dielectric material used in the buildup regions 120, 122 is softer (e.g., less rigid) than the glass core 118. As such, while the glass core 118 provided structural rigidity for the substrate 116, the dielectric material of the buildup regions 120, 122 is better able to withstand stress and deflect or deform without breaking than the glass core 118. In some examples, the dielectric material used in the buildup regions 120, 122 includes layers of epoxy laminate. In some such examples, the dielectric material includes glass fillers and/or glass fibers in the epoxy. In some examples, the dielectric material is Ajinomoto Buildup Film® (ABF).

In the example of FIG. 1, the IC package 104 is a land grid array (LGA) package. Accordingly, in this example, the package contacts 128 on the bottom side of the package 104 (e.g., on the second surface 126 of the substrate 116) are lands that are to interface and electrical couple with corresponding socket contacts 130 (e.g., second contacts, second connectors, socket connectors) in the socket 108, which are pins in this example. In other examples, the IC package 104 can be a ball grid array (BGA) package or a pin grid array (PGA) package with corresponding balls or pins for the package contacts 128 on the package 104 and corresponding lands, balls, pin receptacles, and/or other suitable types of contacts for the socket contacts 130 on the socket 108.

In some examples, the glass core 118 includes at least one of: aluminosilicate, borosilicate, alumino-borosilicate, silica, and/or fused silica. In some examples, the glass core 118 includes one or more additives including: aluminum oxide (Al₂O₃), boron trioxide (B₂O₃), magnesia oxide (MgO), calcium oxide (CaO), stoichiometric silicon oxide (SrO), barium oxide (BaO), stannic oxide (SnO₂), nickel alloy (Na₂O), potassium oxide (K₂O), phosphorus trioxide (P₂O₃), zirconium dioxide (ZrO₂), lithium oxide (Li₂O), titanium (Ti), and/or zinc (Zn). In some examples, the glass core 118 includes silicon and oxygen. In some examples, the glass core 118 includes silicon, oxygen and/or one or more of aluminum, boron, magnesium, calcium, barium, tin, sodium, potassium, strontium, phosphorus, zirconium, lithium, titanium, and/or zinc. In some examples, the glass core 118 includes at least 23 percent silicon by weight and at least 26 percent oxygen by weight. In some examples, the glass core 118 is a layer of glass including silicon, oxygen, and aluminum. In some examples, the core 118 includes at least 23 percent silicon by weight, at least 26 percent oxygen by weight, and at least 5 percent aluminum by weight.

In some examples, the glass core 118 is an amorphous solid glass layer. In some examples, the glass core 118 is a layer of glass that does not include an organic adhesive or an organic material. In some examples, the glass core 118 is a solid layer of glass having a generally rectangular shape in plan view. In some examples, the core 118, as a glass substrate, includes at least one glass layer and does not include epoxy and does not include glass fibers (e.g., does not include an epoxy-based prepreg layer with glass cloth). In some examples, the glass core 118 corresponds to a single piece of glass that extends the full height/thickness of the core. In some examples, the core 118 can be silicon, a dielectric material, and/or any other material(s). In some examples, the core 118 has a generally rectangular shape that is substantially coextensive, in plan view, with the layers (e.g., the buildup regions 120, 122) above and/or below the core 118. However, as discussed further below, in some examples, the glass core 118 includes notches and/or openings at locations close to and/or on the perimeter of the core 118 that are not coextensive with the buildup regions 120, 122.

In some examples, the core 118 has a thickness in a range of about 50 micrometers (μm) to about 1.4 millimeters (mm). In some examples, the core 118 can be a multi-layer glass substrate (e.g., a coreless substrate), where a glass layer has a thickness in a range of about 25 μm to about 50 μm. In some examples, the core 118 can have dimensions of about 10 mm on a side (e.g., a perimeter edge) to about 250 mm on a side (e.g., 10 mm by 10 mm to 250 mm by 250 mm). In some examples, the core 118 corresponds to a generally rectangular prism volume with sections (e.g., vias) removed and filled with other materials (e.g., metal). Among other things, glass cores are advantageous over epoxy-based cores because glass is stiffer and, therefore, provides for greater mechanical support or strength for the package substrate 116. Thus, the glass core 118 is an example means for strengthening the substrate 116.

As shown in the illustrated example, the socket 108 includes a base 132 that houses or contains the socket contacts 130. In this example, the socket contacts 130 are pins that protrude beyond and outward from a first surface 134 (e.g., a package-facing surface, a mounting surface) of the base 132. As noted above, in other examples, the socket contacts 130 can be any other suitable type of contacts (e.g., balls, lands, pin receptacles, etc.) depending on the nature of the corresponding package contacts 128 on the IC package 104. The socket contacts 130 communicatively couple the IC package 104 to the printed circuit board 110. In some examples, the socket 108 includes one or more alignment features 135, 136, 137, 138 that protrude outward and away from the first surface 134 of the base 132. In some examples, the alignment features 135, 136, 137, 138 protrude farther away from the base 132 than the socket contacts 130 protrude from the base 132. In some examples, the alignment features 135, 136, 137, 138 are integral extensions of the base 132. In the illustrated example, the alignment features 135, 136, 137, 138 are detents or datums positioned adjacent the corners of the socket 108 to guide the positioning of the IC package 104 relative to the socket 108. More particularly, as most clearly shown in FIG. 3, each alignment feature 135, 136, 137, 138 extends around a corresponding corner of the IC package 104 to engage two adjacent sides or edges along the outer perimeter of the package 104. In other examples, the alignment features 135, 136, 137, 138 can have different sizes and/or shapes and can be located at different locations from what is shown in the illustrated example.

In FIGS. 1-3, the heatsink 102 is couplable (e.g., thermally couplable) to the IC package 104 to dissipate heat therefrom. In some examples, the heatsink 102 is mechanically coupled to the back plate 112 via fixture elements, loading mechanisms, nuts, or fasteners 140, 142, 144, 146 to place the components between the heatsink 102 and the back plate 112 within the component stack 100 in compression when assembled. The compression created by the mechanical coupling of the heatsink 102 to the back plate 112 via the fasteners 140, 142, 144, 146 serves to ensure that corresponding contacts 128, 130 (e.g., pins, lands, etc.) on the IC package 104 and the socket 108 remain in contact. In some examples, the heatsink 102 is coupled to the back plate 112 via the bolster plate 106 positioned therebetween. More particularly, as shown in FIG. 2, the bolster plate 106 is couplable to a first surface 147 (e.g., top surface, front surface) of the PCB 110 while the back plate 112 is couplable to a second surface 148 (e.g., bottom surface, back surface) of the PCB 110 opposite the bolster plate 106. In this manner, the PCB 110 is sandwiched between the bolster plate 106 and the back plate 112. As shown in FIG. 3, the bolster plate 106 is constructed to surround the socket 108 positioned on the top surface 147 of the PCB 110. In this example, the heatsink 102 is coupled to the bolster plate 106 by the fasteners 140, 142, 144, 146 on the heatsink 102 attaching to corresponding load posts or studs 150, 152, 154, 156 on the bolster plate 106.

For many IC heat dissipation component stacks, such as the example component stack 100 of FIGS. 1-3, each of the four fasteners 140, 142, 144, 146 on the heatsink 102 are tightened one at a time until the stack is fully loaded with the heatsink 102 pressed against the IC package 104 that, in turn, presses the IC package 104 against the socket 108. Inasmuch as the fasteners 140, 142, 144, 146 are tightened sequentially one at a time, the resulting distribution of forces during assembly is not even. For example, when the first fastener 140 is tightened down onto the first load post 150, as represented in the illustrated example of FIG. 4, the portion of the IC package 104 closest to the first fastener 140 is pressed against the socket contacts 130. As a result, the socket contacts 130 closest to the first fastener 140 (which is adjacent the first alignment feature 135) are compressed downward.

The downward compression of the socket contacts 130 can produce significant lateral forces acting on the IC package 104. Specifically, as shown in FIGS. 2 and 4, the socket contacts 130 protrude from the base 132 of the socket 108 upward and to the right (based on the perspective shown in the figures). The socket contacts 130 being angled up and to the right, in this example, produce a reactive force (when compressed downward) that is upward and to the left. As a result, the reactive force not only pushes up on the IC package 104, but also urges the IC package 104 laterally to the left. This lateral component of the reactive force can be sufficient to produce a stress point 158 between the IC package 104 and the second alignment feature 136 (to the left of the package from the perspective shown) that can damage the alignment feature 136.

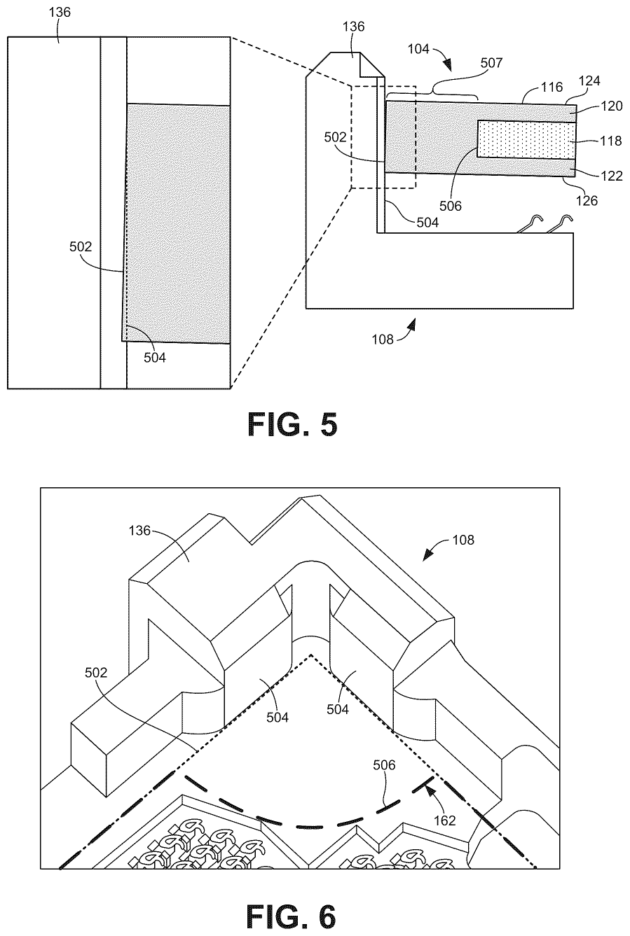

FIG. 5 is an enlarged cross-sectional view of the substrate 116 of the IC package 104 of FIG. 1 pressed against the second alignment feature 136 as shown in FIG. 4. The stress produced at this interface is represented by the perimeter or outer edge 502 (e.g., a third surface extending between the first and second surfaces 124, 126) of the substrate 116 overlapping the alignment guide surface 504 (shown by a dotted line in the region where the components overlap). In some instances, when the second fastener 142 (adjacent the second alignment feature 136) is tightened onto the second load post 152, the IC package 104 is urged downward, thereby causing the outer edge 502 of the IC package 104 scrape along the alignment guide surface 504 of the second alignment feature 136.

In many known IC packages, the glass core of the package substrate extends all the way to the outer edge of the substrate such that the glass core will scrape against the alignment feature. Such scraping can result in skiving of the alignment feature in which material on the outer surface of the alignment feature is stripped away. Such skiving increases the clearance between the package and the socket, which can result in a failure of the component stack because the package contacts do not align with the socket contacts. Furthermore, the stress produced by the lateral forces urging the glass core of a package substrate into the alignment feature can cause damage to (e.g., chipping or cracking of) the glass core.

As shown in FIG. 5, unlike known IC packages in which the glass core extends all the way to the outer edge of the package substrate, the glass core 118 of the example IC package 104 is spaced apart from the alignment feature 136. That is, at least within the plane of the cross-section of FIG. 5, the outer edge 502 of the package substrate 116 extends beyond the perimeter or outer edge 506 of the glass core 118. More particularly, in this example, the material of the buildup regions 120, 122 extend beyond and around the outer edge 506 of the glass core in the area of the second alignment feature 136. That is, in this example, the substrate 116 includes a portion 507 in which the material of the buildup regions 120, 122 extends a full thickness through the substrate 116 (e.g., between both outer (e.g., top and bottom) surfaces 124, 126) without the glass core 118 extending therebetween). In some examples, the portion 507 is within the keep out zone such that there is no metal (e.g., no interconnects) within the portion 507. In other examples, metal interconnect can be constructed to extend through the portion 507 of the dielectric material of the buildup regions 120, 122.

In some examples, while the outer edge 506 of the glass core 118 is inset relative to the outer edge 502 of the substrate at locations adjacent the alignment feature 136, the outer edge 502 of the glass core 118 corresponds to (e.g., is aligned with, defines) the outer edge 502 of the substrate 116 of the package 104 at other locations spaced apart from the alignment feature 136. For instance, as shown in the illustrated example of FIG. 3, the full perimeter or outer edge of the glass core 118 corresponds to the perimeter of the substrate 116 except at the corners of the substrate 116 adjacent to the alignment features 135, 136, 137, 138. As shown in FIG. 3, at the corners of the glass core 118, the perimeter or outer edge of the glass core includes or is defined by notches, voids, apertures, cavities, or openings 160, 162, 164, 166 (shown in dotted lines because the glass core 118 is embedded within the substrate 116). As shown, the openings 160, 162, 164, 166 are sized and positioned so that the glass core 118 remains spaced apart from the alignment features 135, 136, 137, 138, even when lateral forces urge the IC package 104 against the alignment features 135, 136, 137, 138. The IC package 104 of the illustrated example, with the glass cores 118 constructed in this manner, is significantly less likely to cause skiving of the alignment features 135, 136, 137, 138 because the material of the buildup regions 120, 122 is not as hard or rigid as the glass core 118 and, therefore, provides more give at the stress point 158. Furthermore, examples disclosed herein significantly reduce damage to the glass core 118 because the glass core 118 remains separated from the alignment features 135, 136, 137, 138 (e.g., by the material of the buildup regions 120, 122 extending beyond the out edge 506 of the glass core 118). That is, the dielectric material of the buildup regions 120, 122 that is between the alignment feature 136 and the glass core 118 acts as a buffer to reduce stress on the glass core 118.

As shown in FIG. 3, the openings 160, 162, 164, 166 are defined by a generally circular or round shape that extends about an axis corresponding to each corner of the substrate 116 of the IC package 104. In other examples, the openings 160, 162, 164, 166 can be any other suitable shape (e.g., square, triangular, etc.) with edges or contours that may be curved, arcuate, or straight.

FIG. 6 is a perspective view of the example socket 108 of FIGS. 1-5 that shows an enlarged view of the example second alignment feature 136 of FIGS. 1-5. In FIG. 6, the IC package 104 is omitted. However, the location of the perimeter or outer edge 502 of the IC package (e.g., outer edge 502 of the substrate 116 of the IC package 104) is represented by the line drawn with short dashes. Further, the location of the perimeter or outer edge 506 of the glass core 118 of the substrate 116 is represented by the line drawn with long dashes. As shown in the illustrated example, the outer edge 502 of the substrate 116 is aligned with (e.g., interfaces with) the alignment guide surfaces 504 of the second alignment feature 136. As a result, the IC package 104 can be precisely positioned with the socket 108 using the alignment feature 136 as a guide. However, the outer edge 506 of the glass core 118 is spaced apart from the second alignment feature 136 to protect the second alignment feature 136 and/or the glass core 118 from damage. In this example, the glass core 118 is spaced apart from the alignment feature 136 due to the round opening 162 at the corner of the glass core 118. More particularly, as shown in the illustrated example, the round opening 162 has a radius of curvature that is greater than the distance the alignment guide surfaces 504 extend from the corner of the IC package 104. In some examples, the radius of curvature is approximately 3 mm with the alignment guide surfaces 504 extending approximately 2 mm from the corner of the IC package 104. In other examples, the radius of curvature can be greater or less than 3 mm.

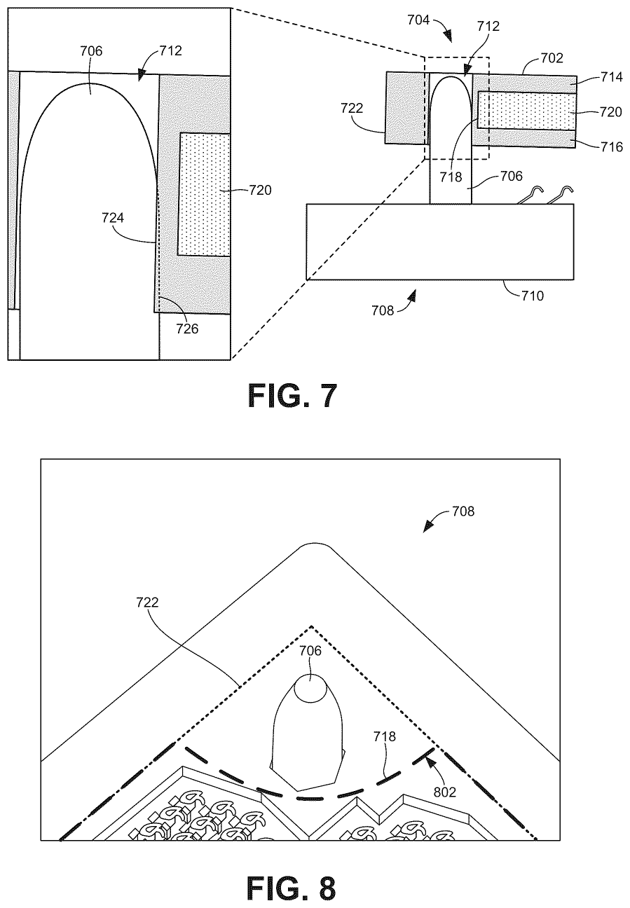

FIG. 7 is a cross-sectional view of an example substrate 702 of another example IC package 704 pressed against another example alignment feature 706 of another example socket 708. In this example, the alignment feature 706 is a guide post that protrudes upwards from a base 710 of the socket 708. In this example, the IC package 704 is aligned with the socket 708 by aligning the guide post (e.g., the alignment feature 706) with a corresponding opening or hole 712 extending through the substrate 702 of the IC package 704. More particularly, in this example, the hole 712 extends through material associated with first and second buildup regions 714, 716 that extend beyond a perimeter or outer edge 718 of a glass core 720 positioned between the buildup regions 714, 716. That is, the hole 712 is positioned between the outer edge 718 of the glass core 720 and the perimeter or outer edge 722 (e.g., a third surface extending between the opposing top and bottom surfaces) of the substrate 702. Thus, as shown in the illustrated example, the glass core 720 remains spaced apart from the alignment feature 706. Instead, it is the dielectric material of the buildup regions 714, 716 that is pressed against the alignment feature 706. The stress produced at this interface is represented by the inner surface or inner wall 724 of the hole 712 overlapping the outer surface or outer wall 726 of the alignment feature 706 (shown by a dotted line in the region where the components overlap). As discussed above, the buildup regions 714, 716 are made of material that is less hard or rigid than the material of the glass core 720 and, therefore, can absorb the stresses involved to reduce (e.g., prevent) damage to the alignment feature 706 and/or to the glass core 720.

FIG. 8 is a perspective view of the example socket 708 of FIG. 7 that shows an enlarged view of the example alignment feature 706 of FIG. 7. In FIG. 8, the IC package 704 is omitted. However, the location of the perimeter or outer edge 722 of the IC package (e.g., outer edge 722 of the substrate 702 of the IC package 704) is represented by the line drawn with short dashes. Further, the location of the perimeter or outer edge 718 of the glass core 720 of the substrate 702 is represented by the line drawn with long dashes. In the illustrated example of FIG. 8, the outer edge 722 of the substrate 702 and the outer edge 724 of the glass core 720 are similar to what is shown in FIG. 5. That is, as shown in FIG. 8, the glass core 720 is spaced apart from the alignment feature 136 due to a round opening 802 at the corner of the glass core 720 that is similar to the round opening 162 of FIG. 5. More particularly, as shown in the illustrated example, the round opening 802 has a radius of curvature that extends around the alignment feature 706.

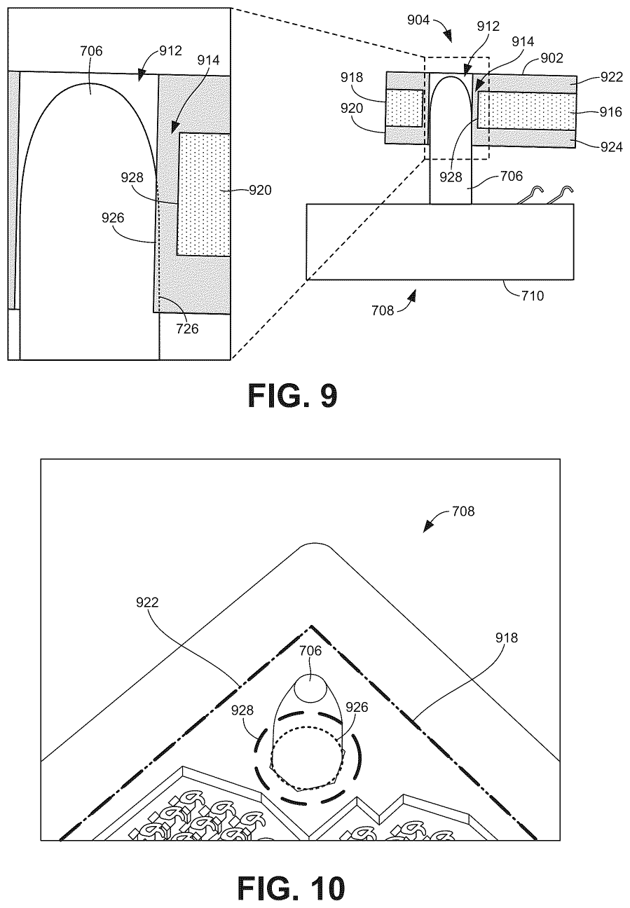

FIG. 9 is a cross-sectional view of another example substrate 902 of another example IC package 904 pressed against the example alignment feature 706 of the example socket 708 of FIGS. 7 and 8. In this example, the IC package 904 is aligned with the socket 708 by aligning the guide post (e.g., the alignment feature 706) with a corresponding opening or hole 912 extending through the substrate 902 of the IC package 904. The hole 912 shown in FIG. 9 is similar to the hole 712 shown in FIG. 7. However, the example shown in FIG. 9 differs from FIG. 7 in that the holes 912 extends through a larger opening or hole 914 in the glass core 916. More particularly, as shown in the illustrated example of FIG. 9, the perimeter or outer edge 918 of the glass core 916 extends all the way to the perimeter or outer edge 920 of the substrate 902 of the IC package 904. However, the alignment feature 706 that extends through the hole 914 in the glass core 916 is nevertheless maintained spaced apart from the glass core 916 due to the size of the hole 914 in the glass core 916 relative to the hole 912 that extends through the material of the buildup regions 922, 924 on either side of the glass core 916. Specifically, as shown in the illustrated example, the inner surface or inner wall 926 of the hole 912 has a smaller width or diameter than the inner surface or inner wall 928 of the hole 914 in the glass core 916. In other words, the material of the buildup regions 922, 924 that defines the inner wall 926 of the hole 912 lines the inner wall 928 of the hole 914 in the glass core 916. Stated differently, the material of the buildup regions 922, 924 define an annular column of the material within the larger hole 914 of the glass core 916, within the inside of the annular column corresponding to the smaller hole 912. In some examples, the smaller hole 912 in the buildup material is coaxially aligned with the larger hole 914 in the glass core 916.

FIG. 10 is a perspective view of the example socket 708 of FIG. 9 that shows an enlarged view of the example alignment feature 706 of FIG. 9. In FIG. 10, the IC package 904 is omitted. However, the location of the perimeter or outer edge 920 of the IC package (e.g., outer edge 920 of the substrate 902 of the IC package 904) is represented by the line drawn with short dashes. Further, the location of the perimeter or outer edge 918 of the glass core 916 of the substrate 902 is represented by the line drawn with long dashes. As shown, in this example, the outer edge 918 of the glass core is aligned with (e.g., corresponds to) the outer edge 920 of the substrate 902. In the illustrated example of FIG. 10, the location of the inner wall 926 of the hole 912 that extends through the substrate 902 is represented by a circular line drawn with short dashes. Further, the location of the inner wall 928 of the hole 914 that extends through the glass core 916 is represented by a circular line drawn with long dashes. As shown, the hole 912 is significantly smaller than the hole 914. In this manner, the smaller hole 912 provides the relatively tight clearance needed to precisely align the IC package 904 with the socket 708, while the larger hole 914 ensures that the glass core remains spaced apart from the alignment feature 706 with dielectric material positioned therebetween as a stress buffer.

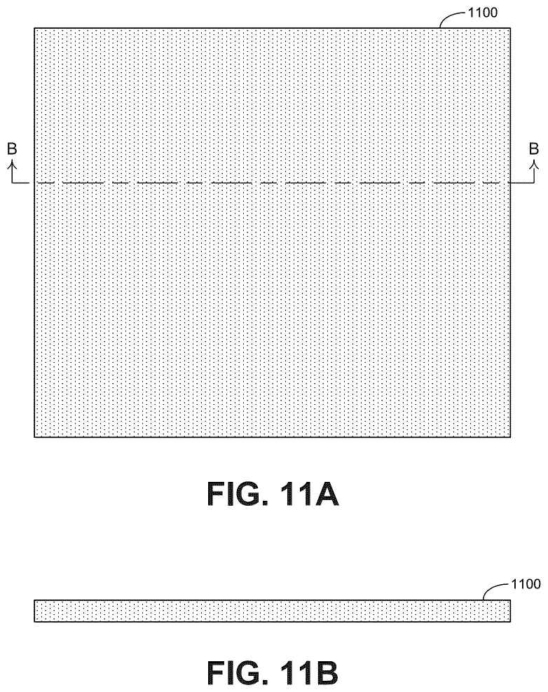

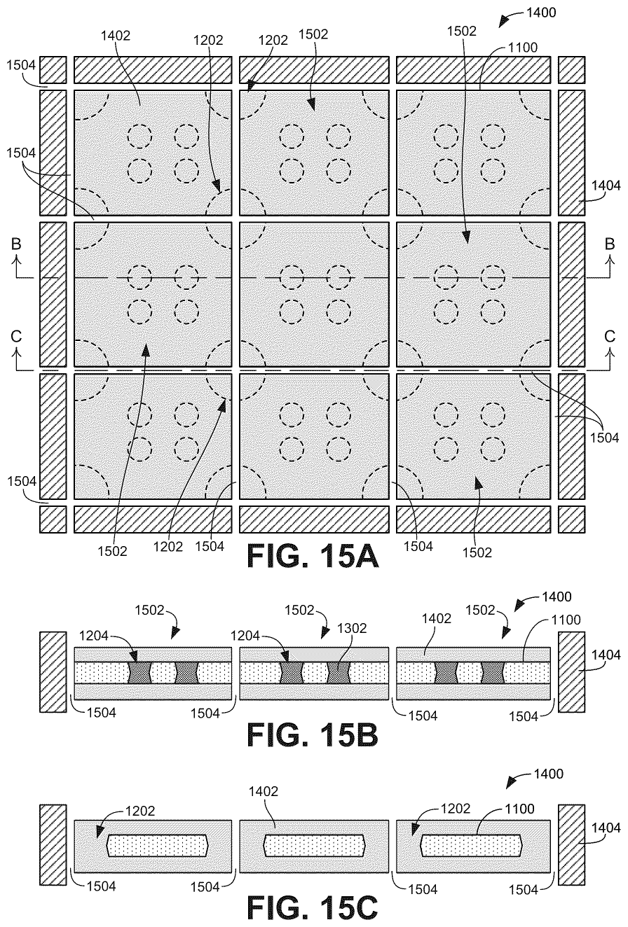

FIGS. 11A-15C illustrate different example stages in an example process to manufacture the example substrate 116 of FIGS. 1-6. Specifically, FIG. 11A is a top view of an example glass panel 1100 prior to any subsequent processing. FIG. 11B is a cross-sectional side view of the glass panel 1100 of FIG. 11A taken along line B-B in FIG. 11A. In this example, the glass panel 1100 is a panel that is intended to be cut (e.g., singulated) into multiple different glass cores for multiple different package substrates. More particularly, as shown further below, the glass panel 1100 is to serve as the basis for nine separate substrates arranged 1502 (shown in FIG. 15A) in a 3×3 grid. In other examples, the glass panel 1100 can be any suitable size and divided into any suitable number of individual substrates.

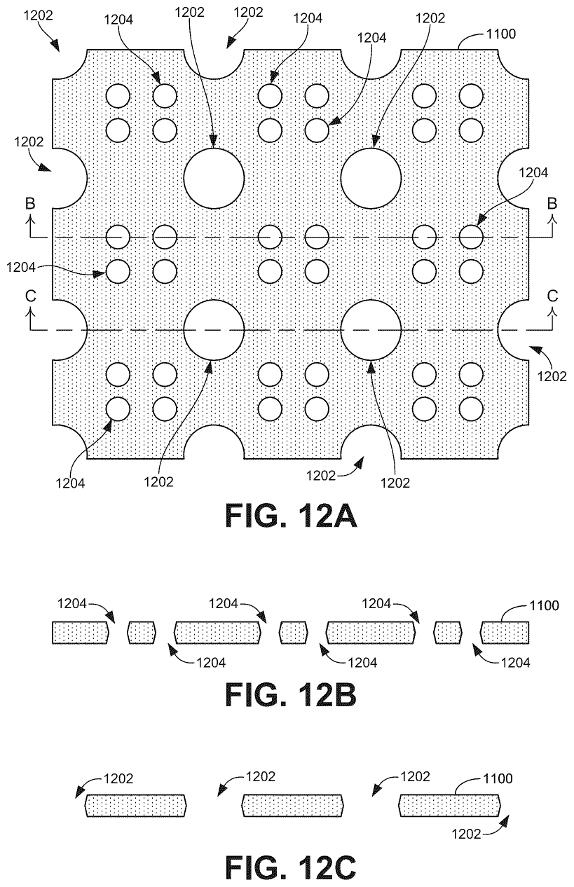

FIG. 12A is a top view of the example glass panel 1100 following the creation of example first cavities, voids, holes, or openings 1202 and example second cavities, voids, holes, or openings 1204. FIG. 12B is a cross-sectional side view of the glass panel 1100 of FIG. 12A taken along line B-B in FIG. 12A. FIG. 12C is a cross-sectional side view of the glass panel 1100 of FIG. 12A taken along line C-C in FIG. 12A. As shown, the cross-sectional view shown in FIG. 12B passes through a row of the second openings 1204 while the cross-sectional view shown in FIG. 12C passes through a row of the second openings 1204.

In this example, the first openings 1202 are larger than the second openings 1204. In some examples, the first openings 1202 serve as the basis for the openings 160, 162, 164, 166 at the corners of the glass core 118 shown in FIG. 1. Thus, in this example, the location of the first openings 1202 align with the corners of the different glass cores to be cut from the glass panel 1100 as discussed further below. The second openings 1204 serve as through glass vias (TGVs) that are to be subsequently plated with metal to provide electrical connectivity between the metal interconnects in the buildup regions 120, 122 on either side of the glass panel 1100. Thus, while only four different second openings 1204 are shown grouped together in the central region of each glass core to be cut out of the glass panel 1100, there may be any suitable number of second openings 1204 in any suitable arrangement.

In some examples, the first and second openings 1202, 1204 are created through a laser drilling process (e.g., laser induced voiding process) that removes the glass material at the locations of the openings 1202, 1204. In some examples, the laser drilling process etches part way through the glass panel 1100 from either side to produce the through-hole. In such examples, the profile of the openings 1202, 1204 can have a generally hour-glass shape as shown in the illustrated examples. In other examples, the drilling process can go all the way through the glass panel 1100 from only one side. In some such examples, the profile of the openings 1202, 1204 may be generally conical. In some examples, the profile of the openings 1202, 1204 is generally straight and substantially perpendicular to the outer surfaces of the glass panel 1100. As noted above, the first openings 1202 are significantly larger than the second openings 1204. Accordingly, in some examples, the removal of the glass material to define the first openings 1202 requires multiple passes of a laser. More particularly, in some examples, a laser is rasterized across the entire area of glass to be removed. In some such examples, the material is completely removed during an associated wet etch. In other examples, rather than directly removing all of the material by a laser induced voiding process, a laser can be exposed at incremental points along a line defining the perimeter or outline of the first openings 1202. Once the full outline of the first openings 1202 have been etched away, in such examples, the rest of the glass material associated with the first openings 1202 will drop out and/or can otherwise be removed.

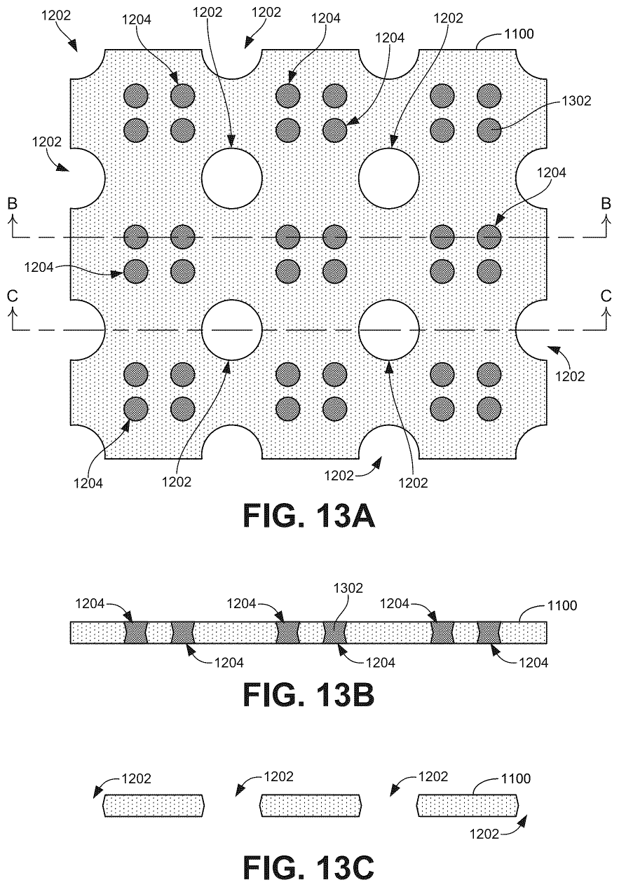

FIG. 13A is a top view of the example glass panel 1100 following the addition of metal 1302 (e.g., copper) into the second openings 1204. FIG. 13B is a cross-sectional side view of the glass panel 1100 of FIG. 13A taken along line B-B in FIG. 13A. FIG. 13C is a cross-sectional side view of the glass panel 1100 of FIG. 13A taken along line C-C in FIG. 13A. In some examples, the metal 1302 is added into the second openings 1204 through a plating process. In some examples, a seed layer is first deposited through an electroless plating process followed by the rest of the metal 1302 deposited through an electrolytic plating process. While the second openings 1204 have been filled with the metal 1302, the first openings 1204 remain empty. In some examples, the first openings 1204 are prevented from being filled by the metal 1302 by first covering the first openings 1204 with a mask. More particularly, in some examples, the entire glass panel 1100 is covered by a resist film that is photolithographically patterned to uncover the second openings 1204 while keeping the first openings 1202 covered. Then, the plating process is performed to deposit the metal 1302 into the second openings 1204. Thereafter, an etching process is implemented to remove the patterned resist material. In some examples, an additional etching and/or planarization process is implemented to remove excess metal 1302.

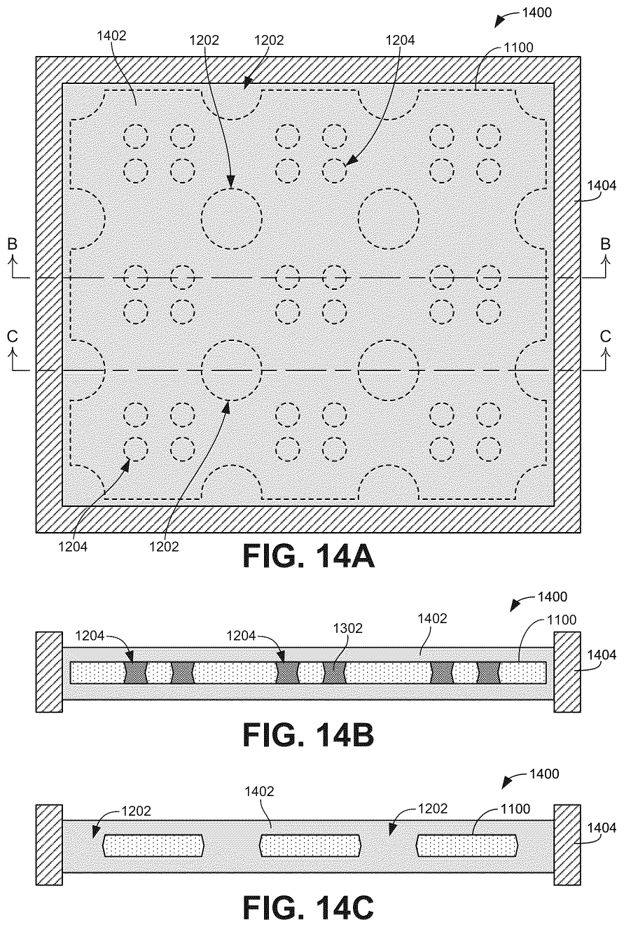

FIG. 14A is a top view of an example glass panel assembly 1400 that includes the example glass panel 1100 enclosed by example dielectric material 1402 associated with the buildup regions 120, 122 on either side of the glass panel 1100. FIG. 14B is a cross-sectional side view of the glass panel assembly 1400 of FIG. 14A taken along line B-B in FIG. 14A. FIG. 14C is a cross-sectional side view of the glass panel assembly 1400 of FIG. 14A taken along line C-C in FIG. 14A. At the stage in the process shown in FIGS. 14A-14C, the glass panel 1100 is entirely enclosed or encased by the dielectric material 1402. Accordingly, the glass panel 1100 is shown in dashed lines in the illustrated example of FIG. 14A.

In some examples, the dielectric material 1402 is a mold compound that is molded around the glass panel 1100. In some examples, the dielectric material 1402 is laminated in layers onto both surfaces of the glass panel 1100. As shown in FIG. 14C, the dielectric material 1402 fills the first openings 1202. In some examples, a frame 1404 is added around the outer perimeter of the dielectric material 1402 to provide structural support during subsequent processing.

FIG. 15A is a top view of the example glass panel assembly 1400 of FIG. 14A following singulation of the glass panel assembly 1400 into multiple discrete package substrates 1502 (e.g., corresponding to the example substrate 116 of FIGS. 1-6). FIG. 15B is a cross-sectional side view of the glass panel assembly 1400 of FIG. 15A taken along line B-B in FIG. 15A. FIG. 15C is a cross-sectional side view of the glass panel assembly 1400 of FIG. 15A taken along line C-C in FIG. 15A. In this example, the glass panel assembly 1400 (including the glass panel 1100 and associated dielectric material 1402) is singulated or cut by a saw that follows a series of saw streets 1504. In this example, the saw streets 1504 define the perimeter or outer edge (e.g., the outer edge 502 of FIG. 5) of the different package substrates 1502. As shown in the illustrated example, the saw streets 1504 are aligned with (e.g., pass through) the second openings 1202. As a result, the corners of the resulting substrates 1502 do not include glass along the outer edge of the substrates 1502 (as shown in FIG. 15C). However, in this example, the glass still extends to the outer edge at locations spaced apart from the corners as shown in FIG. 15B.

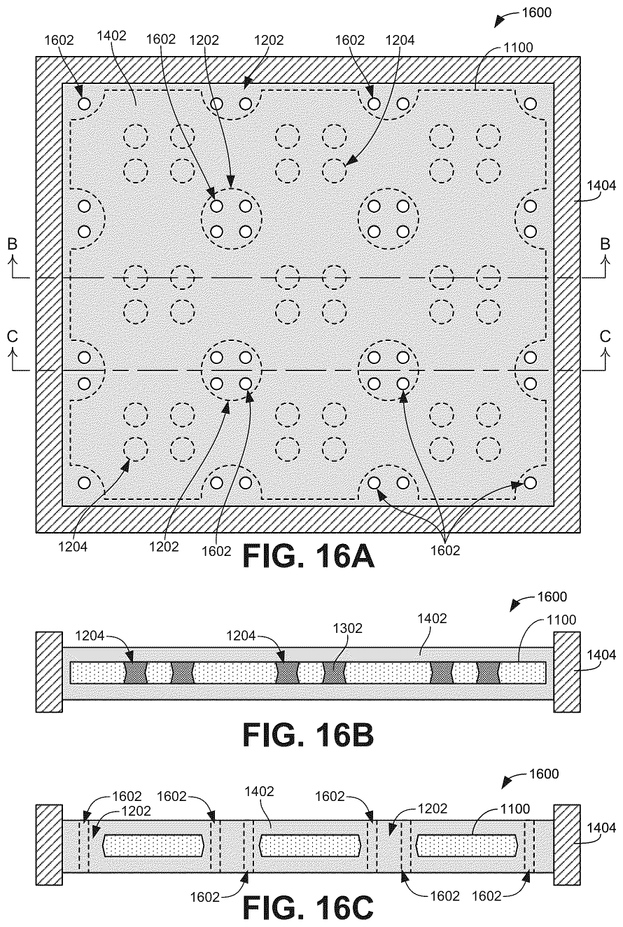

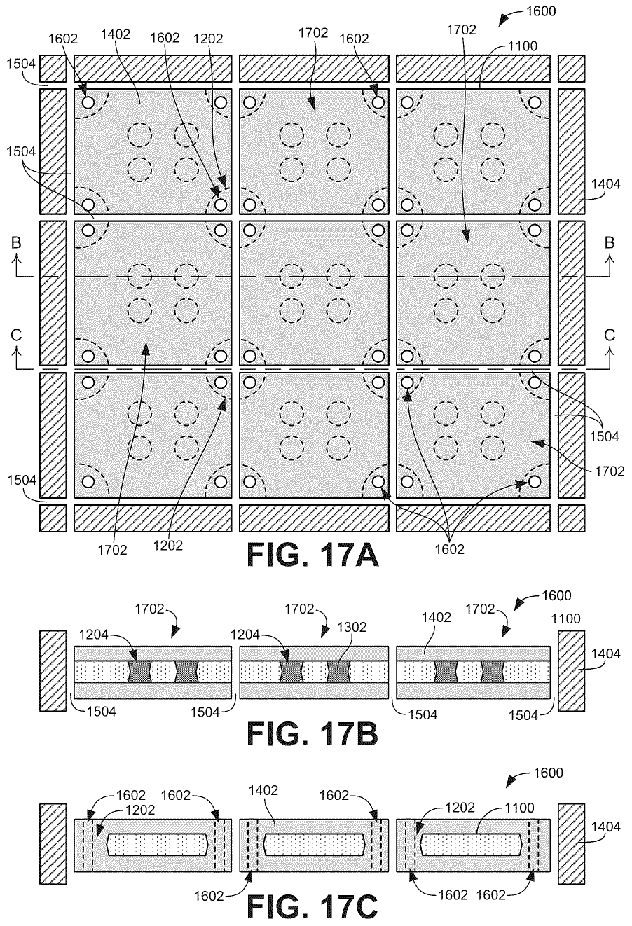

FIGS. 16A-17C illustrate different example stages in an example process to manufacture the example substrate 702 of FIGS. 7 and 8. The manufacturing process of this example follows the same stages of manufacture represented in FIGS. 11A-14C discussed above with FIGS. 16A-16C representing a subsequent stage in the fabrication process. Thus, the same reference numbers used in FIGS. 11A-14C will be used for the same or similar features shown in FIGS. 16A-17C. Further, the description of such features provided above in connection with FIGS. 11A-14C applies similarly to the same features shown in FIGS. 16A-17C.

FIG. 16A is a top view of an example glass panel assembly 1600 including the glass panel 1100 embedded in the dielectric material 1402 after the addition of holes 1602 extending through the dielectric material 1402. As shown in the illustrated example, the holes 1602 are positioned within (e.g., extend through) the first openings 1202. The holes 1602 correspond to the example hole 712 in FIG. 7 that is to receive the guide post (e.g., the alignment feature 706) to facilitate alignment of the IC package 704 with the socket 708. FIG. 16B is a cross-sectional side view of the glass panel 1100 of FIG. 16A taken along line B-B in FIG. 16A. FIG. 16C is a cross-sectional side view of the glass panel 1100 of FIG. 16A taken along line C-C in FIG. 16A. In FIG. 16C, the holes 1602 are represented in dashed lines because the holes 1602 are not in the plane of the cross-sectional view but they are relatively close to the cross-sectional plane.

FIG. 17A is a top view of the example glass panel assembly 1600 of FIG. 16A following singulation of the glass panel assembly 1600 into multiple discrete package substrates 1702 (e.g., corresponding to the example substrate 116 of FIGS. 1-6). FIG. 17B is a cross-sectional side view of the glass panel assembly 1600 of FIG. 17A taken along line B-B in FIG. 17A. FIG. 17C is a cross-sectional side view of the glass panel assembly 1600 of FIG. 17A taken along line C-C in FIG. 17A. As shown in the illustrated examples, the holes 1602 are located adjacent to each of the corners of each substrate 1702 to engage with alignment features (e.g., guide posts) as discussed above. Inasmuch as the holes 1602 extend through the openings 1202, the glass is kept spaced apart from such alignment features with the dielectric material 1402 (that defines the holes 1602) acting as a stress buffer between the glass cores and the associated holes. Although four example holes 1602 are shown in each substrate 1702 of the illustrated example, in other examples, any other suitable number of holes 1602 may be employed. Further, in some examples, the holes 1602 can be at different places and/or have different sizes than what is shown in the illustrated example. In some examples, at least one of the holes 1602 on each substrate 1702 is a different size from the other holes 1602 to define an asymmetric pattern of hole sizes that corresponds to different sizes of guide posts. In this manner, there will be only one way in which the substrates 1702 will fit over the guide posts, thereby preventing a user from inadvertently placing the resulting package into an associated socket backwards.

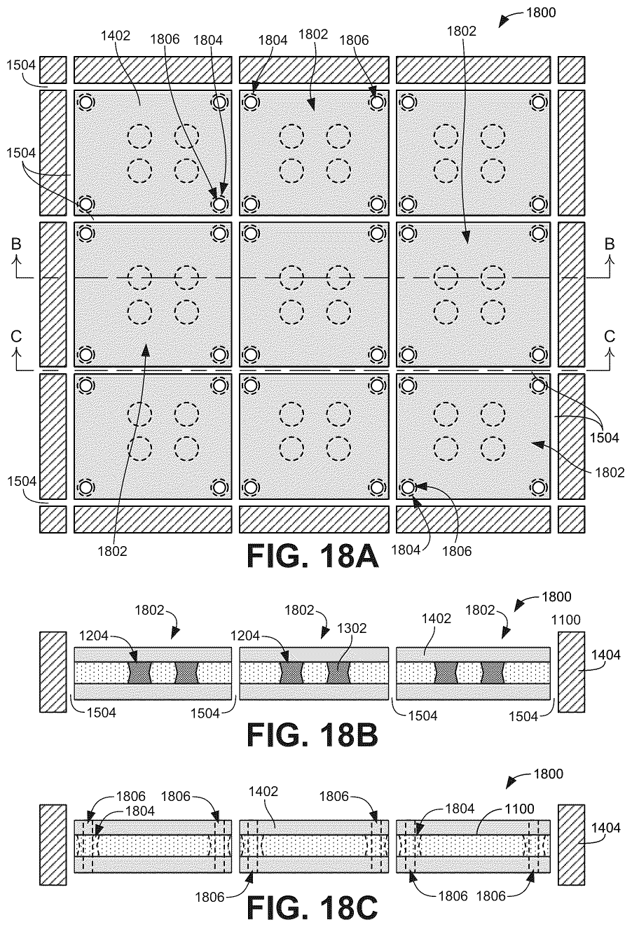

FIGS. 18A-18C illustrate another example glass panel assembly 1800 after singulation into discrete package substrates 1802. The manufacturing process of this example is similar to the example process outlined above for FIGS. 11A-17C. Thus, the same reference numbers used in FIGS. 11A-18C will be used for the same or similar features shown in FIGS. 18A-18C. Further, the description of such features provided above in connection with FIGS. 11A-17C applies similarly to the same features shown in FIGS. 18A-18C.

FIG. 18A is a top view of the example glass panel assembly 1800. FIG. 18B is a cross-sectional side view of the glass panel assembly 1800 of FIG. 18A taken along line B-B in FIG. 18A. FIG. 18C is a cross-sectional side view of the glass panel assembly 1600 of FIG. 18A taken along line C-C in FIG. 18A. In this example, the first openings 1202 shown in FIGS. 11B-17C are omitted. Instead, example third openings 1804 are positioned within the glass panel at locations that are adjacent to but spaced apart from the outer edge of the final glass cores of the substrates 1802. As a result, unlike in the examples of FIGS. 11A-17C, the glass core of each substrate 1802 in FIGS. 18A-18C extends to the outer edge of the substrate 1802 at the corners of the substrate. Thus, in FIG. 18C, both the third openings 1804 and the smaller holes 1806 are shown in dashed lines because they are inset relative to the cross-sectional plane associated with the illustrated example.

In this example, the third openings 1804 are initially filled with the dielectric material 1402 similar to the way the first openings 1202 are filled with the dielectric material 1402 discussed above in connection with FIGS. 14A-14C. Further, in this example, smaller holes 1806 are drilled through the dielectric material 1402 at locations within the third openings 1804. The example smaller holes 1806 are similar to the holes 1602 in FIGS. 16A-16C and sized and positioned to engage with the alignment feature 706 (e.g., guide post) of the socket 708 as shown in FIGS. 9 and 10. Due to the smaller diameter of the holes 1806 relative to the third openings 1804, at least some of the dielectric material 1402 remains on the inner surface or wall of the third openings 1804 to provide a buffer between the alignment feature 706 and the glass core inside each substrate 1802.

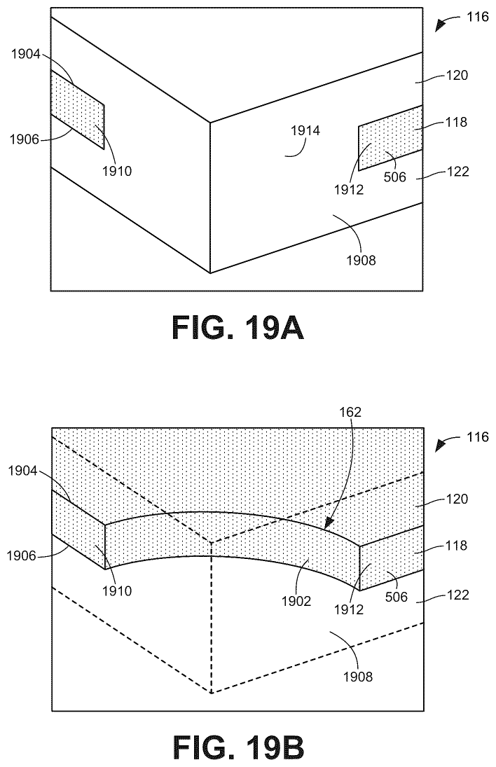

FIG. 19A is a perspective view of a corner of the example substrate 116 of FIGS. 1-6. FIG. 19B shows the same view as FIG. 19A but with the dielectric material 1908 of the buildup regions 120, 122 rendered see-through to show the glass core 118 embedded therein. As shown in the illustrated example, the glass core 118 includes an opening 162 defined by a sidewall 1902 extending between opposing sides 1904, 1906 of the glass core 118. In this example, the dielectric material 1908 extends along the sidewall 1902 to fill the opening 162 between the buildup regions 120, 122. In this example, the opening 162 is a notch along a perimeter or outer edge 506 of the glass core 118. More particularly, in this example, the notch is at the corner of the glass core 118. In other words, the opening 162 is positioned along an outer perimeter (e.g., the outer edge 506) of the glass core 118 between first and second straight segments 1910, 1912 of the outer perimeter. In this example, the first straight segment 1910 of the outer perimeter extends in a direction transvers to (e.g., perpendicular to) the second straight segment 1910, 1912. In this example, the first and second straight segments extend along different portions of the outer perimeter of the substrate 116. In other words, in some examples, an outer surface 1914 of the dielectric material 1908 is coplanar with the first and second straight segments 1910, 1912. In some examples, the outer surface 1914 of the dielectric material 1908 engages the alignment features 135, 136, 137, 138 while the coplanar first and second segments 1910, 1912 of the glass core 118 remain spaced apart from the alignment features.

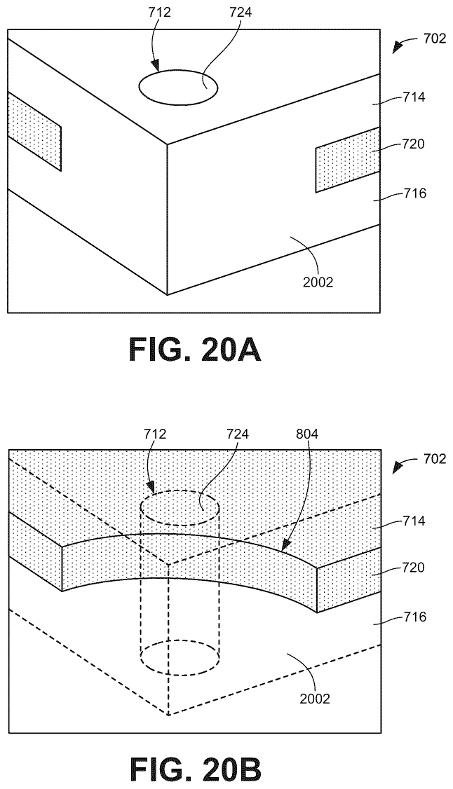

FIG. 20A is a perspective view of a corner of the example substrate 702 of FIGS. 7 and 8. FIG. 20B shows the same view as FIG. 20A but with the dielectric material 2002 of the buildup regions 714, 716 rendered see-through to show the glass core 720 embedded therein. As shown in the illustrated example, the glass core 720 of FIGS. 20A and 20B includes an opening 804 that is similar to the opening 162 of FIGS. 19A and 19B. However, in the illustrated example of FIGS. 20A and 20B, the dielectric material 2002 includes or defines the hole 712 with the inner wall 724 of the hole 712 defining a surface extending between the top and bottom surfaces of the package substrate 702. As discussed above in connection with FIGS. 7 and 8, the surface of the inner wall 724 is to engage with the alignment feature 706 and maintain the glass core 720 spaced apart from the alignment feature 706.

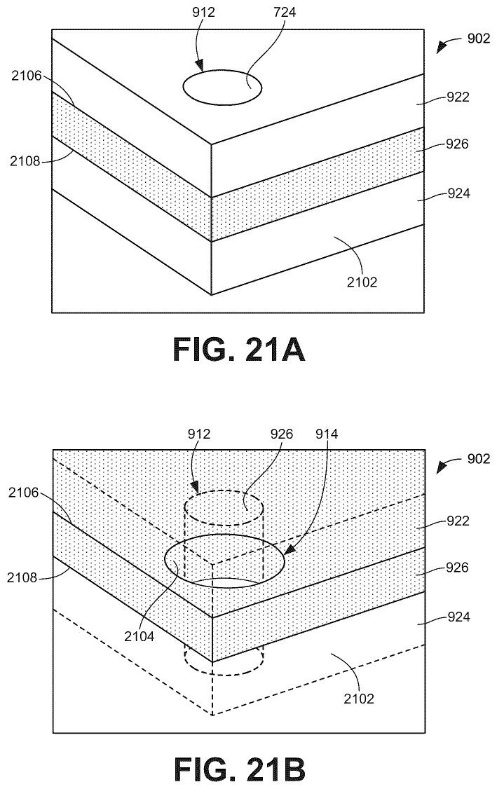

FIG. 21A is a perspective view of a corner of the example substrate 902 of FIGS. 9 and 10. FIG. 21B shows the same view as FIG. 21A but with the dielectric material 2102 of the buildup regions 922, 924 rendered see-through to show the glass core 916 embedded therein. As shown in the illustrated example, the glass core 916 of FIGS. 21A and 21B includes an opening or hole 914 that includes a sidewall 2104 that extends between opposing sides 2106, 2108 of the glass core 916. Further, in this example, the dielectric material 2102 includes or defines the hole 912 with an inner wall 926 of the hole 912 defining a surface extending between the top and bottom surfaces of the package substrate 902. In this example, the hole 912 passes through the hole 914 in the glass core 916. However, in this example, the inner wall 926 is spaced apart from the sidewall 2104 of the hole 914 because of the different sizes of the holes 912, 914.

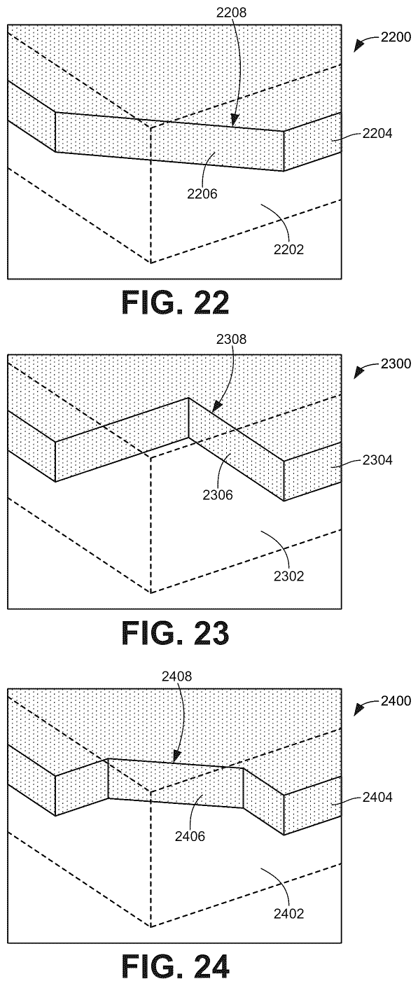

FIG. 22 is a perspective view of a corner of another example substrate 2200 with the dielectric material 2202 rendered see-through to show the glass core 2204 embedded therein. In this example, the glass core 2204 includes or defines an opening 2206 that has a sidewall 2208 that is planar. More particularly, in this example, the sidewall 2208 includes a single planar surface that extends between two separate side edges of the substrate 2200 such that the opening 2208 has a generally triangular shape. Although no hole is shown extending through the dielectric material 2202, in some examples, the dielectric material 2202 includes a hole similar to what is shown in FIGS. 20A and 20B to enable alignment of the substrate 2200 with a socket using a guide post as the alignment feature.

FIG. 23 is a perspective view of a corner of another example substrate 2300 with the dielectric material 2302 rendered see-through to show the glass core 2304 embedded therein. In this example, the glass core 2304 includes or defines an opening 2306 that has a sidewall 2308 that is planar. More particularly, in this example, the sidewall 2308 includes two planar surfaces such that the opening 2308 has a generally rectangular or square shape. Although no hole is shown extending through the dielectric material 2302, in some examples, the dielectric material 2302 includes a hole similar to what is shown in FIGS. 20A and 20B to enable alignment of the substrate 2300 with a socket using a guide post as the alignment feature.

FIG. 24 is a perspective view of a corner of another example substrate 2400 with the dielectric material 2402 rendered see-through to show the glass core 2404 embedded therein. In this example, the glass core 2404 includes or defines an opening 2406 that has a sidewall 2408 that is planar. More particularly, in this example, the sidewall 2408 includes three planar surfaces. In other examples, any suitable number of planar surfaces can be used to define the sidewall 2408. In other examples, the surfaces may be curved or arcuate. Further, in some examples, the sidewall 2408 can be defined by both planar and curved or arcuate surfaces in any suitable arrangement. Although no hole is shown extending through the dielectric material 2402, in some examples, the dielectric material 2402 includes a hole similar to what is shown in FIGS. 20A and 20B to enable alignment of the substrate 2400 with a socket using a guide post as the alignment feature.

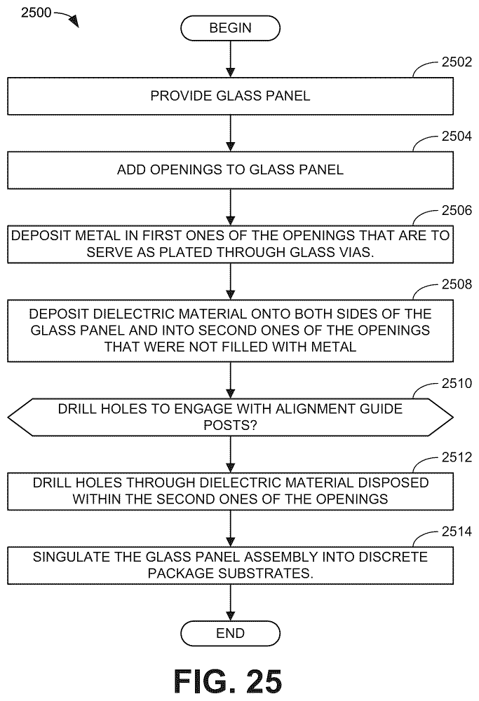

FIG. 25 is a flowchart representative of an example method 2500 that may be performed to fabricate any one of the example package substrates 116, 702, 902, 1502, 1702, 1802, 2200, 2300, 2400 disclosed herein. In some examples, some or all of the operations outlined in the example method of FIG. 25 are performed automatically by equipment that is programmed to perform the operations. Although the example method is described with reference to the flowchart illustrated in FIG. 25, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example method 2500 of FIG. 25 begins at block 2502 by providing a glass panel. At block 2504, the example method involves adding openings to the glass panel. At block 2506, the example method involves depositing metal in first ones of the openings that are to serve as plated through holes. In some such examples, second ones of the openings are covered before the plating process so that they are not filled with the metal. At block 2508, the example method involves depositing dielectric material onto both sides of the glass panel and into the second ones of the openings that were not filled with the metal. At block 2510, the example method determines whether to drill holes to engage with alignment guide posts. If so, the example method advances to block 2512 where holes are drilled through the dielectric material disposed within the second ones of the openings. In this example, the holes that are drilled are smaller than the size of the second ones of the openings so that at least some of the dielectric material remains on the sidewalls of the second ones of the openings. Thereafter, at block 2514, the example method involves singulating the glass panel assembly into discrete package substrates. In examples where it is determines (at block 2510) not to drill holes, the example process advances directly to block 2514. Thereafter, the example method of FIG. 25 ends.

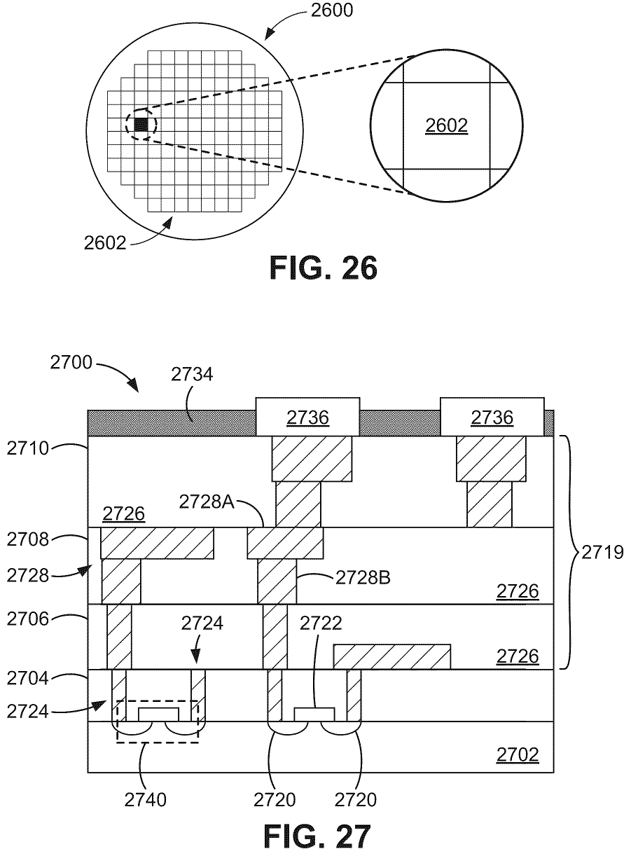

The example IC packages containing any of the example package substrates 116, 702, 902, 1502, 1702, 1802, 2200, 2300, 2400 disclosed herein may be included in any suitable electronic component. FIGS. 26-30 illustrate various examples of apparatus that may include or be included in the example IC packages disclosed herein.

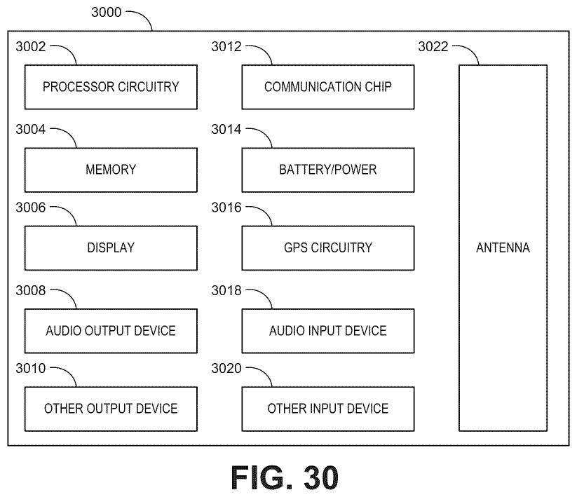

FIG. 26 is a top view of a wafer 2600 and dies 2602 that may be included in an IC package containing an example package substrate 116, 702, 902, 1502, 1702, 1802, 2200, 2300, 2400 in accordance with any of the examples disclosed herein. The wafer 2600 includes semiconductor material and one or more dies 2602 having circuitry. Each of the dies 2602 may be a repeating unit of a semiconductor product. After the fabrication of the semiconductor product is complete, the wafer 2600 may undergo a singulation process in which the dies 2602 are separated from one another to provide discrete “chips.” The die 2602 includes one or more transistors (e.g., some of the transistors 2740 of FIG. 27, discussed below), supporting circuitry to route electrical signals to the transistors, passive components (e.g., traces, resistors, capacitors, inductors, and/or other circuitry), and/or any other components. In some examples, the die 2602 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 2602. For example, a memory array of multiple memory circuits may be formed on a same die 2602 as programmable circuitry (e.g., the processor circuitry 3002 of FIG. 30) and/or other logic circuitry. Such memory may store information for use by the programmable circuitry. The example IC packages disclosed herein may be manufactured using a die-to-wafer assembly technique in which some dies are attached to a wafer 2600 that includes others of the dies, and the wafer 2600 is subsequently singulated.

FIG. 27 is a cross-sectional side view of an IC device 2700 that may be included in an IC package containing an example package substrate 116, 702, 902, 1502, 1702, 1802, 2200, 2300, 2400 in accordance with any of the examples disclosed herein. One or more of the IC devices 2700 may be included in one or more dies 2602 (FIG. 26). The IC device 2700 may be formed on a die substrate 2702 (e.g., the wafer 2600 of FIG. 26) and may be included in a die (e.g., the die 2602 of FIG. 26). The die substrate 2702 may be a semiconductor substrate including semiconductor materials including, for example, n-type or p-type materials systems (or a combination of both). The die substrate 2702 may include, for example, a crystalline substrate formed using a bulk silicon or a silicon-on-insulator (SOI) substructure. In some examples, the die substrate 2702 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 2702. Although a few examples of materials from which the die substrate 2702 may be formed are described here, any material that may serve as a foundation for an IC device 2700 may be used. The die substrate 2702 may be part of a singulated die (e.g., the dies 2602 of FIG. 26) or a wafer (e.g., the wafer 2600 of FIG. 26).

The IC device 2700 may include one or more device layers 2704 disposed on and/or above the die substrate 2702. The device layer 2704 may include features of one or more transistors 2740 (e.g., metal oxide semiconductor field-effect transistors (MOSFETs)) formed on the die substrate 2702. The device layer 2704 may include, for example, one or more source and/or drain (S/D) regions 2720, a gate 2722 to control current flow between the S/D regions 2720, and one or more S/D contacts 2724 to route electrical signals to/from the S/D regions 2720. The transistors 2740 may include additional features not depicted for the sake of clarity, such as device isolation regions, gate contacts, and the like. The transistors 2740 are not limited to the type and configuration depicted in FIG. 27 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 2740 may include a gate 2722 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 2740 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 2740 along the source-channel-drain direction, the gate electrode may include a U-shaped structure that includes a bottom portion substantially parallel to the surface of the die substrate 2702 and two sidewall portions that are substantially perpendicular to the top surface of the die substrate 2702. In other examples, at least one of the metal layers that form the gate electrode may be a planar layer that is substantially parallel to the top surface of the die substrate 2702 and does not include sidewall portions substantially perpendicular to the top surface of the die substrate 2702. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 2720 may be formed within the die substrate 2702 adjacent to the gate 2722 of corresponding transistor(s) 2740. The S/D regions 2720 may be formed using an implantation/diffusion process or an etching/deposition process, for example. In the former process, dopants such as boron, aluminum, antimony, phosphorous, or arsenic may be ion-implanted into the die substrate 2702 to form the S/D regions 2720. An annealing process that activates the dopants and causes them to diffuse farther into the die substrate 2702 may follow the ion-implantation process. In the latter process, the die substrate 2702 may first be etched to form recesses at the locations of the S/D regions 2720. An epitaxial deposition process may then be carried out to fill the recesses with material that is used to fabricate the S/D regions 2720. In some implementations, the S/D regions 2720 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 2720 may be formed using one or more alternate semiconductor materials such as germanium or a group III-V material or alloy. In further examples, one or more layers of metal and/or metal alloys may be used to form the S/D regions 2720.

Electrical signals, such as power and/or input/output (I/O) signals, may be routed to and/or from the devices (e.g., transistors 2740) of the device layer 2704 through one or more interconnect layers disposed on the device layer 2704 (illustrated in FIG. 27 as interconnect layers 2706-2710). For example, electrically conductive features of the device layer 2704 (e.g., the gate 2722 and the S/D contacts 2724) may be electrically coupled with the interconnect structures 2728 of the interconnect layers 2706-2710. The one or more interconnect layers 2706-2710 may form a metallization stack (also referred to as an “ILD stack”) 2719 of the IC device 2700.

The interconnect structures 2728 may be arranged within the interconnect layers 2706-2710 to route electrical signals according to a wide variety of designs (in particular, the arrangement is not limited to the particular configuration of interconnect structures 2728 depicted in FIG. 27). Although a particular number of interconnect layers 2706-2710 is depicted in FIG. 27, examples of the present disclosure include IC devices having more or fewer interconnect layers than depicted.

In some examples, the interconnect structures 2728 may include lines 2728a and/or vias 2728b filled with an electrically conductive material such as a metal. The lines 2728a may be arranged to route electrical signals in a direction of a plane that is substantially parallel with a surface of the die substrate 2702 upon which the device layer 2704 is formed. For example, the lines 2728a may route electrical signals in a direction in and/or out of the page from the perspective of FIG. 27. The vias 2728b may be arranged to route electrical signals in a direction of a plane that is substantially perpendicular to the surface of the die substrate 2702 upon which the device layer 2704 is formed. In some examples, the vias 2728b may electrically couple lines 2728a of different interconnect layers 2706-2710 together.

The interconnect layers 2706-2710 may include a dielectric material 2726 disposed between the interconnect structures 2728, as shown in FIG. 27. In some examples, the dielectric material 2726 disposed between the interconnect structures 2728 in different ones of the interconnect layers 2706-2710 may have different compositions; in other examples, the composition of the dielectric material 2726 between different interconnect layers 2706-2710 may be the same.

A first interconnect layer 2706 (referred to as Metal 1 or “M1”) may be formed directly on the device layer 2704. In some examples, the first interconnect layer 2706 may include lines 2728a and/or vias 2728b, as shown. The lines 2728a of the first interconnect layer 2706 may be coupled with contacts (e.g., the S/D contacts 2724) of the device layer 2704.

A second interconnect layer 2708 (referred to as Metal 2 or “M2”) may be formed directly on the first interconnect layer 2706. In some examples, the second interconnect layer 2708 may include vias 2728b to couple the lines 2728a of the second interconnect layer 2708 with the lines 2728a of the first interconnect layer 2706. Although the lines 2728a and the vias 2728b are structurally delineated with a line within each interconnect layer (e.g., within the second interconnect layer 2708) for the sake of clarity, the lines 2728a and the vias 2728b may be structurally and/or materially contiguous (e.g., simultaneously filled during a dual-damascene process) in some examples.

A third interconnect layer 2710 (referred to as Metal 3 or “M3”) (and additional interconnect layers, as desired) may be formed in succession on the second interconnect layer 2708 according to similar techniques and/or configurations described in connection with the second interconnect layer 2708 or the first interconnect layer 2706. In some examples, the interconnect layers that are “higher up” in the metallization stack 2719 in the IC device 2700 (i.e., further away from the device layer 2704) may be thicker.

The IC device 2700 may include a solder resist material 2734 (e.g., polyimide or similar material) and one or more conductive contacts 2736 formed on the interconnect layers 2706-2710. In FIG. 27, the conductive contacts 2736 are illustrated as taking the form of bond pads. The conductive contacts 2736 may be electrically coupled with the interconnect structures 2728 and configured to route the electrical signals of the transistor(s) 2740 to other external devices. For example, solder bonds may be formed on the one or more conductive contacts 2736 to mechanically and/or electrically couple a chip including the IC device 2700 with another component (e.g., a circuit board). The IC device 2700 may include additional or alternate structures to route the electrical signals from the interconnect layers 2706-2710; for example, the conductive contacts 2736 may include other analogous features (e.g., posts) that route the electrical signals to external components.

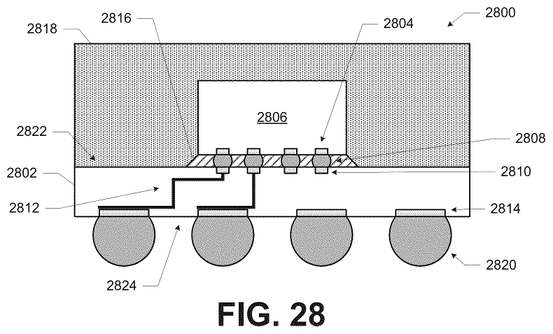

FIG. 28 is a cross-sectional view of an example IC package 2800 constructed in accordance with teachings disclosed herein. The package substrate 2802 may include a dielectric material, and may have conductive pathways extending through the dielectric material between upper and lower faces 2822, 2824, and/or between different locations on the upper face 2822, and/or between different locations on the lower face 2824. These conductive pathways may take the form of any of the interconnects 2728 discussed above with reference to FIG. 27. In some examples, the substrate 2802 is constructed in accordance with one of the example package substrate 116, 702, 902, 1502, 1702, 1802, 2200, 2300, 2400 disclosed herein.

The IC package 2800 may include a die 2806 coupled to the package substrate 2802 via conductive contacts 2804 of the die 2806, first-level interconnects 2808, and conductive contacts 2810 of the package substrate 2802. The conductive contacts 2810 may be coupled to conductive pathways 2812 through the package substrate 2802, allowing circuitry within the die 2806 to electrically couple to various ones of the conductive contacts 2814 (or to other devices included in the package substrate 2802, not shown). The first-level interconnects 2808 illustrated in FIG. 28 are solder bumps, but any suitable first-level interconnects 2808 may be used. As used herein, a “conductive contact” refers to a portion of conductive material (e.g., metal) serving as an electrical interface between different components. Conductive contacts may be recessed in, flush with, or extending away from a surface of a component, and may take any suitable form (e.g., a conductive pad or socket).

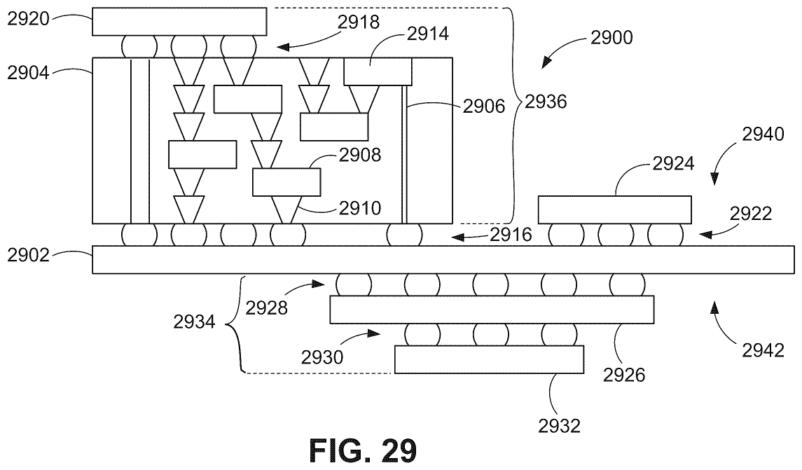

In some examples, an underfill material 2816 may be disposed between the die 2806 and the package substrate 2802 around the first-level interconnects 2808, and/or a mold compound 2818 may be disposed around the die 2806 and in contact with the package substrate 2802. In some examples, the underfill material 2816 may be the same as the mold compound 2818. Example materials that may be used for the underfill material 2816 and the mold compound 2818 are epoxy mold materials, as suitable. Second-level interconnects 2820 may be coupled to the conductive contacts 2814. The second-level interconnects 2820 illustrated in FIG. 28 are solder balls (e.g., for a ball grid array arrangement), but any suitable second-level interconnects 2820 may be used (e.g., pins in a pin grid array arrangement or lands in a land grid array arrangement). The second-level interconnects 2820 may be used to couple the IC package 2800 to another component, such as a circuit board (e.g., a motherboard), an interposer, or another IC package, as known in the art and as discussed below with reference to FIG. 29.

In FIG. 28, the IC package 2800 is a flip chip package. The die 2806 may take the form of any of the examples of the die discussed herein (e.g., may include any of the examples of the IC device 2700). Although the IC package 2800 illustrated in FIG. 28 is a flip chip package, other package architectures may be used. For example, the IC package 2800 may be a ball grid array (BGA) package, such as an embedded wafer-level ball grid array (eWLB) package. In another example, the IC package 2800 may be a wafer-level chip scale package (WLCSP) or a panel fanout (FO) package. Although a single die 2806 is illustrated in the IC package 2800 of FIG. 28, an IC package 2800 may include multiple dies 2806. An IC package 2800 may include additional passive components, such as surface-mount resistors, capacitors, and/or inductors disposed on the first face 2822 or the second face 2824 of the package substrate 2802. More generally, an IC package 2800 may include any other active and/or passive components known in the art.

FIG. 29 is a cross-sectional side view of an IC device assembly 2900 that may include one or more of the example package substrates 116, 702, 902, 1502, 1702, 1802, 2200, 2300, 2400 disclosed herein. The IC device assembly 2900 includes a number of components disposed on a circuit board 2902 (which may be, for example, a motherboard). The IC device assembly 2900 includes components disposed on a first face 2940 of the circuit board 2902 and an opposing second face 2942 of the circuit board 2902; generally, components may be disposed on one or both faces 2940 and 2942.

In some examples, the circuit board 2902 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2902. In other examples, the circuit board 2902 may be a non-PCB substrate.

The IC device assembly 2900 illustrated in FIG. 29 includes a package-on-interposer structure 2936 coupled to the first face 2940 of the circuit board 2902 by coupling components 2916. The coupling components 2916 may electrically and mechanically couple the package-on-interposer structure 2936 to the circuit board 2902, and may include solder balls (as shown in FIG. 29), male and female portions of a socket, an adhesive, an underfill material, and/or any other suitable electrical and/or mechanical coupling structure.

The package-on-interposer structure 2936 may include an IC package 2920 coupled to an interposer 2904 by coupling components 2918. The coupling components 2918 may take any suitable form for the application, such as the forms discussed above with reference to the coupling components 2916. Although a single IC package 2920 is shown in FIG. 29, multiple IC packages may be coupled to the interposer 2904; indeed, additional interposers may be coupled to the interposer 2904. The interposer 2904 may provide an intervening substrate used to bridge the circuit board 2902 and the IC package 2920. The IC package 2920 may be or include, for example, a die (the die 2602 of FIG. 26), an IC device (e.g., the IC device 2700 of FIG. 27), or any other suitable component. Generally, the interposer 2904 may spread a connection to a wider pitch or reroute a connection to a different connection. For example, the interposer 2904 may couple the IC package 2920 (e.g., a die) to a set of BGA conductive contacts of the coupling components 2916 for coupling to the circuit board 2902. In the example illustrated in FIG. 29, the IC package 2920 and the circuit board 2902 are attached to opposing sides of the interposer 2904; in other examples, the IC package 2920 and the circuit board 2902 may be attached to a same side of the interposer 2904. In some examples, three or more components may be interconnected by way of the interposer 2904.

In some examples, the interposer 2904 may be formed as a PCB, including multiple metal layers separated from one another by layers of dielectric material and interconnected by electrically conductive vias. In some examples, the interposer 2904 may be formed of an epoxy resin, a fiberglass-reinforced epoxy resin, an epoxy resin with inorganic fillers, a ceramic material, or a polymer material such as polyimide. In some examples, the interposer 2904 may be formed of alternate rigid or flexible materials that may include the same materials described above for use in a semiconductor substrate, such as silicon, germanium, and other group III-V and group IV materials. The interposer 2904 may include metal interconnects 2908 and vias 2910, including but not limited to through-silicon vias (TSVs) 2906. The interposer 2904 may further include embedded devices 2914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 2904. The package-on-interposer structure 2936 may take the form of any of the package-on-interposer structures known in the art.

The IC device assembly 2900 may include an IC package 2924 coupled to the first face 2940 of the circuit board 2902 by coupling components 2922. The coupling components 2922 may take the form of any of the examples discussed above with reference to the coupling components 2916, and the IC package 2924 may take the form of any of the examples discussed above with reference to the IC package 2920.

The IC device assembly 2900 illustrated in FIG. 29 includes a package-on-package structure 2934 coupled to the second face 2942 of the circuit board 2902 by coupling components 2928. The package-on-package structure 2934 may include a first IC package 2926 and a second IC package 2932 coupled together by coupling components 2930 such that the first IC package 2926 is disposed between the circuit board 2902 and the second IC package 2932. The coupling components 2928, 2930 may take the form of any of the examples of the coupling components 2916 discussed above, and the IC packages 2926, 2932 may take the form of any of the examples of the IC package 2920 discussed above. The package-on-package structure 2934 may be configured in accordance with any of the package-on-package structures known in the art.

FIG. 30 is a block diagram of an example electrical device 3000 that may include one or more of the example package substrates 116, 702, 902, 1502, 1702, 1802, 2200, 2300, 2400 disclosed herein. For example, any suitable ones of the components of the electrical device 3000 may include one or more of the device assemblies 2900, IC devices 2700, or dies 2602 disclosed herein. A number of components are illustrated in FIG. 30 as included in the electrical device 3000, but any one or more of these components may be omitted or duplicated, as suitable for the application. In some examples, some or all of the components included in the electrical device 3000 may be attached to one or more motherboards. In some examples, some or all of these components are fabricated onto a single system-on-a-chip (SoC) die.

Additionally, in various examples, the electrical device 3000 may not include one or more of the components illustrated in FIG. 30, but the electrical device 3000 may include interface circuitry for coupling to the one or more components. For example, the electrical device 3000 may not include a display 3006, but may include display interface circuitry (e.g., a connector and driver circuitry) to which a display 3006 may be coupled. In another set of examples, the electrical device 3000 may not include an audio input device 3018 (e.g., microphone) or an audio output device 3008 (e.g., a speaker, a headset, earbuds, etc.), but may include audio input or output device interface circuitry (e.g., connectors and supporting circuitry) to which an audio input device 3018 or audio output device 3008 may be coupled.

The electrical device 3000 may include programmable circuitry 3002 (e.g., one or more processing devices). The programmable circuitry 3002 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 3000 may include a memory 3004, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 3004 may include memory that shares a die with the programmable circuitry 3002. This memory may be used as cache memory and may include embedded dynamic random access memory (eDRAM) or spin transfer torque magnetic random access memory (STT-MRAM).

In some examples, the electrical device 3000 may include a communication chip 3012 (e.g., one or more communication chips). For example, the communication chip 3012 may be configured for managing wireless communications for the transfer of data to and from the electrical device 3000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 3012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 3012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 3012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 3012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 3012 may operate in accordance with other wireless protocols in other examples. The electrical device 3000 may include an antenna 3022 to facilitate wireless communications and/or to receive other wireless communications (such as AM or FM radio transmissions).

In some examples, the communication chip 3012 may manage wired communications, such as electrical, optical, or any other suitable communication protocols (e.g., the Ethernet). As noted above, the communication chip 3012 may include multiple communication chips. For instance, a first communication chip 3012 may be dedicated to shorter-range wireless communications such as Wi-Fi or Bluetooth, and a second communication chip 3012 may be dedicated to longer-range wireless communications such as global positioning system (GPS), EDGE, GPRS, CDMA, WiMAX, LTE, EV-DO, or others. In some examples, a first communication chip 3012 may be dedicated to wireless communications, and a second communication chip 3012 may be dedicated to wired communications.

The electrical device 3000 may include battery/power circuitry 3014. The battery/power circuitry 3014 may include one or more energy storage devices (e.g., batteries or capacitors) and/or circuitry for coupling components of the electrical device 3000 to an energy source separate from the electrical device 3000 (e.g., AC line power).

The electrical device 3000 may include a display 3006 (or corresponding interface circuitry, as discussed above). The display 3006 may include any visual indicators, such as a heads-up display, a computer monitor, a projector, a touchscreen display, a liquid crystal display (LCD), a light-emitting diode display, or a flat panel display.

The electrical device 3000 may include an audio output device 3008 (or corresponding interface circuitry, as discussed above). The audio output device 3008 may include any device that generates an audible indicator, such as speakers, headsets, or earbuds.

The electrical device 3000 may include an audio input device 3018 (or corresponding interface circuitry, as discussed above). The audio input device 3018 may include any device that generates a signal representative of a sound, such as microphones, microphone arrays, or digital instruments (e.g., instruments having a musical instrument digital interface (MIDI) output).

The electrical device 3000 may include GPS circuitry 3016. The GPS circuitry 3016 may be in communication with a satellite-based system and may receive a location of the electrical device 3000, as known in the art.

The electrical device 3000 may include any other output device 3010 (or corresponding interface circuitry, as discussed above). Examples of the other output device 3010 may include an audio codec, a video codec, a printer, a wired or wireless transmitter for providing information to other devices, or an additional storage device.

The electrical device 3000 may include any other input device 3020 (or corresponding interface circuitry, as discussed above). Examples of the other input device 3020 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 3000 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 3000 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that reduce stress experienced between glass cores in substrates of IC packages and alignment features of sockets into which the IC packages are inserted. This is achieved, in some examples, by constructing the glass cores to include holes, openings, or voids at locations where the alignment features on a socket are located and then at least partially filling the holes, openings, or voids with a dielectric material that serves as a buffer between the glass cores and the alignment features.

Further examples and combinations thereof include the following:
Example 1 includes an integrated circuit package comprising a semiconductor die, and a substrate including a glass core, the substrate including a first surface, a second surface opposite the first surface, and a third surface between the first surface and the second surfaces, the first surface to support the semiconductor die, the second surface including first contacts to electrical couple with second contacts in a socket, at least a portion of the third surface separated and distinct from the glass core.
Example 2 includes the integrated circuit package of example 1, wherein the substrate includes a dielectric material, the dielectric material defining the at least the portion of the third surface.
Example 3 includes the integrated circuit package of example 2, wherein the glass core includes an opening between opposing sides of the glass core, the dielectric material in the opening between the glass core and the at least the portion of the third surface.
Example 4 includes the integrated circuit package of example 3, wherein the opening is a notch along an outer edge of the glass core.
Example 5 includes the integrated circuit package of example 4, wherein the notch is at a corner of the glass core.
Example 6 includes the integrated circuit package of any one of examples 3-5, wherein the dielectric material fills a space within the opening in the glass core.
Example 7 includes the integrated circuit package of any one of examples 3-6, wherein the dielectric material defines a hole extending through the opening, an inner wall of the hole defining the third surface.
Example 8 includes the integrated circuit package of any one of examples 3-7, wherein the opening is defined by a sidewall that includes a planar surface.
Example 9 includes the integrated circuit package of any one of examples 3-8, wherein the opening is defined by a sidewall that includes an arcuate surface.
Example 10 includes the integrated circuit package of any one of examples 3-9, wherein the opening is a hole extending through the glass core, the hole spaced apart from an outer edge of the glass core.
Example 11 includes the integrated circuit package of example 10, wherein the hole is a first hole in the glass core, the dielectric material defining a second hole coaxially aligned with the first hole.
Example 12 includes a package substrate comprising a glass core, a first buildup region on a first side of the glass core, the first buildup region supporting and electrically coupled to a semiconductor die, and a second buildup region on a second side of the glass core, the second buildup region including first contacts to electrically interface with second contacts in a socket, and dielectric material between the first and second buildup regions through an opening in the glass core, the dielectric material to separate the glass core from an alignment feature on the socket.
Example 13 includes the package substrate of example 12, wherein the opening is located along an outer perimeter of the glass core, the opening between first and second straight segments of the outer perimeter.
Example 14 includes the package substrate of example 13, wherein the first straight segment extends in a direction transverse to the second straight segment.
Example 15 includes the package substrate of any one of examples 13 or 14, wherein the dielectric material includes an outer surface that is coplanar with at least one of the first straight segment or the second straight segment.
Example 16 includes the package substrate of example 15, wherein the alignment feature is a detent and the outer surface of the dielectric material is to engage with the detent while the glass core remains spaced apart from the detent.
Example 17 includes the package substrate of any one of examples 13-16, wherein the alignment feature is a guide post and the dielectric material defines a hole spaced apart from an outer surface of the dielectric material, the hole dimensioned to at least partially receive the guide post.
Example 18 includes the package substrate of any one of examples 12-17, wherein the opening is a first hole spaced apart from an outer perimeter of the glass core, the dielectric material defines a second hole within the first hole, and the alignment feature is a guide post to be received into the first hole, the first hole having a first width, the second hole having a second width, the second width smaller than the first width.
Example 19 includes the package substrate of any one of examples 12-18, wherein the opening is a first opening at a first corner of the glass core, and the dielectric material is first dielectric material, the glass core including a second opening at a second corner of the glass core, second dielectric material extending between the first and second buildup regions through the second opening.
Example 20 includes an apparatus comprising a socket, and an integrated circuit package to be inserted into the socket, the integrated circuit package including a package substrate having a glass core, the socket including an alignment feature to engage with the package substrate to guide a position of the integrated circuit package relative to the socket, the alignment feature to extend farther away from a mounting surface of the socket than the glass core is from the mounting surface of the socket when the integrated circuit package is inserted into the socket, the glass core including an opening to maintain separation between the alignment feature and the glass core.
Example 21 includes the apparatus of example 20, wherein the package substrate includes a dielectric material lining the opening of the glass core.
Example 22 includes the apparatus of any one of examples 20 or 21, further including at least one of a keyboard of a display.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

1. An integrated circuit package comprising:
a semiconductor die; and
a substrate including a glass core, the substrate including a first surface, a second surface opposite the first surface, and a third surface between the first surface and the second surfaces, the first surface to support the semiconductor die, the second surface including first contacts to electrical couple with second contacts in a socket, at least a portion of the third surface separated and distinct from the glass core.

2. The integrated circuit package of claim 1, wherein the substrate includes a dielectric material, the dielectric material defining the at least the portion of the third surface.

3. The integrated circuit package of claim 2, wherein the glass core includes an opening between opposing sides of the glass core, the dielectric material in the opening between the glass core and the at least the portion of the third surface.

4. The integrated circuit package of claim 3, wherein the opening is a notch along an outer edge of the glass core.

5. The integrated circuit package of claim 4, wherein the notch is at a corner of the glass core.

6. The integrated circuit package of claim 3, wherein the dielectric material fills the opening in the glass core.

7. The integrated circuit package of claim 3, wherein the dielectric material defines a hole extending through the opening, an inner wall of the hole defining the third surface.

8. The integrated circuit package of claim 3, wherein the opening is defined by a sidewall that includes a planar surface.

9. The integrated circuit package of claim 3, wherein the opening is defined by a sidewall that includes an arcuate surface.

10. The integrated circuit package of claim 3, wherein the opening is a hole extending through the glass core, the hole spaced apart from an outer edge of the glass core.

11. The integrated circuit package of claim 10, wherein the hole is a first hole in the glass core, the dielectric material defining a second hole coaxially aligned with the first hole.

12. A package substrate comprising:
a glass core;
a first buildup region on a first side of the glass core, the first buildup region supporting and electrically coupled to a semiconductor die; and
a second buildup region on a second side of the glass core, the second buildup region including first contacts to electrically interface with second contacts in a socket; and
dielectric material between the first and second buildup regions through an opening in the glass core, the dielectric material to separate the glass core from an alignment feature on the socket.

13. The package substrate of claim 12, wherein the opening is located along an outer perimeter of the glass core, the opening between first and second straight segments of the outer perimeter.

14. (canceled)

15. The package substrate of claim 13, wherein the dielectric material includes an outer surface that is coplanar with at least one of the first straight segment or the second straight segment.

16. The package substrate of claim 15, wherein the alignment feature is a detent and the outer surface of the dielectric material is to engage with the detent while the glass core remains spaced apart from the detent.

17. The package substrate of claim 13, wherein the alignment feature is a guide post and the dielectric material defines a hole spaced apart from an outer surface of the dielectric material, the hole dimensioned to at least partially receives the guide post.

18. The package substrate of claim 12, wherein the opening is a first hole spaced apart from an outer perimeter of the glass core, the dielectric material defines a second hole within the first hole, and the alignment feature is a guide post to be received into the first hole, the first hole having a first width, the second hole having a second width, the second width smaller than the first width.

19. (canceled)

20. An apparatus comprising:
a socket; and
an integrated circuit package to be inserted into the socket, the integrated circuit package including a package substrate having a glass core, the socket including an alignment feature to engage with the package substrate to guide a position of the integrated circuit package relative to the socket, the alignment feature to extend farther away from a mounting surface of the socket than the glass core is from the mounting surface of the socket when the integrated circuit package is inserted into the socket, the glass core including an opening to maintain separation between the alignment feature and the glass core.

21. The apparatus of claim 20, wherein the package substrate includes a dielectric material lining the opening of the glass core.

22. The apparatus of claim 20, further including at least one of a keyboard of a display.
